(19) United States
(12) Patent Application Publication
(10) Pub. No.: US 2012/0049349 A1
(43) Pub. Date: Mar. 1, 2012

(54) SEMICONDUCTOR CHIPS AND METHODS OF FORMING THE SAME

(75) Inventors: Ho-Jin LEE, Seoul (KR); Donghyeon JANG, Yongin-si (KR); Hogeon SONG, Suwon-si (KR); SeYoung JEONG, Suwon-si (KR); Minseung YOON, Seoul (KR); Jung-Hwan KIM, Bucheon-si (KR)

(73) Assignee: SAMSUNG ELECTRONICS CO., LTD., Suwon-si (KR)

(21) Appl. No.: 13/178,156

(22) Filed: Jul. 7, 2011

(30) Foreign Application Priority Data
Aug. 30, 2010 (KR) 10-2010-0084224

(51) Int. Cl. H01L 23/498; H01L 21/28

(52) U.S. Cl. 257/737; 438/667; 257/E23.068; 257/E21.158; 257/774

(57) ABSTRACT

Provided is a semiconductor chip including a back side insulation structure. The semiconductor chip may include a semiconductor layer including an active surface and an inactive surface facing each other; the insulating layer includes a first surface adjacent to the inactive surface and a second surface facing the first surface. The insulating layer is disposed on the inactive surface of the semiconductor layer. A penetrating electrode fills a hole penetrating the semiconductor layer and the insulating layer. The through electrode comprises a protrusive portion protruding from the second surface of the insulating layer.

### CROSS-REFERENCE TO RELATED APPLICATIONS

This U.S. non-provisional patent application claims priority under 35 U.S.C. § 119 of Korean Patent Application No. 10-2010-0084224, filed on Aug. 30, 2010, the entire contents of which are hereby incorporated by reference.

### BACKGROUND

The inventive concept herein relates to semiconductor chips and methods of forming the same. More particularly, the inventive concept relates to semiconductor chips, including backside insulation structures and methods of forming the same.

Recently, requirements for lightweight, miniaturization, high speed, various functionalizations, high performance and high reliability have been increased in the electronic industry, such as in cell phones and notebook computers. Studies for semiconductor package technology have been continuously done in order to meet those requirements. A two dimensional connection between integrated circuits using existing wire bonding has disadvantages of signal loss, high power consumption and limitations of the design method. To overcome those disadvantages, a three dimensional integrated circuit package technology of connecting stacked semiconductor chips using a vertical interconnection has been suggested. The vertical interconnection which vertically connects semiconductor chips is called a through electrode. A three dimensional integrated circuit package technology using a through electrode may realize more integrated circuits in a same room and may realize shorter connection between the circuits. Various studies for improving electrical characteristics and reliability of semiconductor packages using three dimensional integrated circuit package technology, using the through electrode, have been carried out.

### SUMMARY

Embodiments of the inventive concept may provide semiconductor chips improving reliability and characteristics.

Embodiments of the inventive concept may provide methods of forming semiconductor chips improving productivity.

Embodiments of the inventive concept may provide semiconductor chips. A semiconductor chip may include a semiconductor layer which includes an active surface and an inactive surface facing each other; an insulating layer including a first surface adjacent to the inactive surface and a second surface facing the first surface. The insulating layer may be disposed on the inactive surface of the semiconductor layer; and a penetrating electrode fills a hole penetrating the semiconductor layer and the insulating layer. The through electrode includes a protrusive portion which protrudes from the second surface of the insulating layer.

Embodiments of the inventive concept also provide a method of forming a semiconductor chip. The method may include preparing a substrate comprising a semiconductor layer, a semiconductor substrate and an insulating layer disposed between the semiconductor layer and the semiconductor substrate, the insulating layer including a first surface adjacent to the semiconductor layer and a second surface adjacent to the semiconductor substrate; forming a penetration hole sequentially penetrating the semiconductor layer and the insulating layer, a bottom surface of the penetration hole being formed to be lower than the second surface of the insulating layer; forming a through electrode in the penetration hole; and removing the semiconductor substrate using the insulating layer as an etch-stop layer.

Embodiments of the inventive concept also provide a method of forming a semiconductor chip. The method may include preparing a bulk substrate including a front side and a back side facing each other; forming a hole extending from the front side of the bulk substrate toward the back side of the bulk substrate in the bulk substrate; forming a through electrode in the hole; reducing a thickness of the bulk substrate by etching the back side of the bulk substrate; and forming an insulating layer by preparing an element for insulating property in the bulk substrate through the etched back side.

### BRIEF DESCRIPTION OF THE FIGURES

The accompanying figures are included to provide a further understanding of the exemplary embodiments, and are incorporated in and constitute a part of this specification. The drawings illustrate exemplary embodiments and, together with the description, serve to explain principles of the inventive concept. In the figures:

FIGS. 1 through 8 are cross sectional views illustrating a method of forming a semiconductor chip in accordance with an exemplary embodiment.

FIG. 9 is a cross sectional view for illustrating a semiconductor chip in accordance with an exemplary embodiment.

FIGS. 10 through 17 are cross sectional views illustrating a method of forming a semiconductor chip in accordance with another exemplary embodiment.

FIG. 18 is a cross sectional view illustrating a semiconductor chip in accordance with another exemplary embodiment.

### DETAILED DESCRIPTION OF EXEMPLARY EMBODIMENTS

Exemplary embodiments of the inventive concept will be described below in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Like numbers refer to like elements throughout the disclosure.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the drawings, the thickness of layers and regions are exaggerated for purposes of clarity. It will also be understood that when an element such as a layer, region or substrate is referred to as being “on” or “onto” another element, it may lie directly on the other element or intervening elements or layers may also be present.

Embodiments of the inventive concept may be described with reference to cross-sectional illustrations, which are schematic illustrations of idealized exemplary embodiments. As such, variations from the shapes of the illustrations, as a result, for example, of manufacturing techniques and/or tolerances, are to be expected. Thus, embodiments of the exemplary embodiments should not be construed as limited to the particular shapes of regions illustrated herein, but are to include deviations in shapes that result from, e.g., manufacturing. For example, a region illustrated as a rectangle may have rounded or curved features, etc. Thus, the regions illustrated in the figures are schematic in nature and are not intended to limit the scope of the exemplary embodiments.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings and suggestions of the disclosure.

### First Embodiment

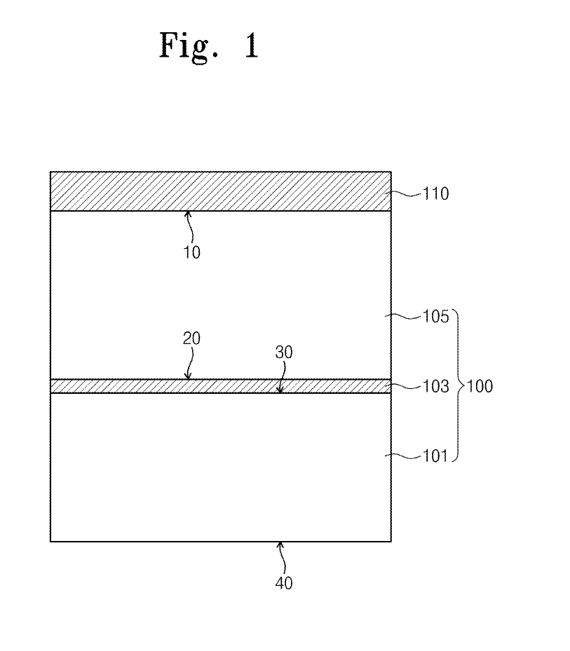

Hereinafter, a method of forming a semiconductor chip in accordance with an exemplary embodiment, is described. FIGS. 1 through 8 are cross sectional views illustrating a method of forming a semiconductor chip in accordance with an exemplary embodiment.

Referring to FIG. 1, a substrate 100 including a semiconductor substrate 101, an insulating layer 103 and a semiconductor layer 105 is prepared. Semiconductor layer 105 may include an active surface 10 and an inactive surface 20 facing each other. The active surface 10 of the semiconductor layer 105 may include at least one of a transistor, a diode, a capacitor or a resistor constituting the semiconductor device. On the other hand, inactive surface 20 of semiconductor layer 105 may not include the aforementioned structure. Semiconductor layer 105 may include semiconductor material. For example, semiconductor layer 105 may include at least one of silicon or germanium.

Semiconductor substrate 101 may include semiconductor material. For example, semiconductor substrate 101 may include at least one of silicon or germanium. According to an exemplary embodiment, semiconductor substrate 101 and semiconductor layer 105 may include a same material.

Insulating layer 103 may include a first surface and a second surface 30 facing away from each other. Insulating layer 103 may be disposed between semiconductor substrate 101 and semiconductor layer 105. Thus, the first surface of insulating layer 103 may contact inactive surface 20 and the second surface 30 of insulating layer 103 may contact a top surface of the semiconductor substrate 101. Insulating layer 103 may include at least one of a silicon oxide, silicon nitride or silicon oxynitride.

Substrate 100 may be formed by providing elements for insulating properties to one surface of a bulk substrate, thereby forming the insulating layer 103. The elements for insulating properties may be provided in a predetermined depth from one surface of the bulk substrate and the elements for insulating properties may react to the semiconductor material included in the bulk substrate in order to form insulating layer 103. At this time, a portion of the bulk substrate between insulating layer 103 and one surface of the bulk substrate may correspond to semiconductor layer 105. Also, a portion of the bulk substrate between insulating layer 103 and the other surface of the bulk substrate may correspond to semiconductor substrate 101. Therefore, substrate 100 may be formed to include semiconductor substrate 101, insulating layer 103 and semiconductor layer 105. The elements for insulating properties may include at least one of oxygen or nitrogen.

Alternatively, substrate 100 may be formed by forming insulating layer 103 on semiconductor substrate 101, bonding a support substrate including semiconductor layer 105 to the first surface of insulating layer 103, and then removing the support substrate from semiconductor layer 105.

Referring back to FIG. 1, a first interlayer dielectric film 110 may be formed on active surface 10 of semiconductor layer 105. First interlayer dielectric film 110 may be formed by a chemical vapor deposition (CVD) process or a physical vapor deposition (PVD) process. First interlayer dielectric film 110 may include at least one of silicon oxide, silicon nitride or silicon oxynitride.

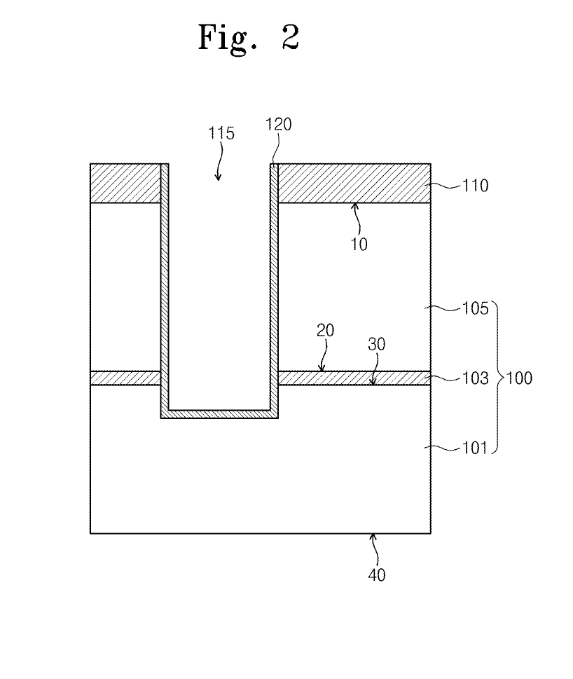

Referring to FIG. 2, a penetration hole 115 sequentially penetrating first interlayer dielectric film 110, semiconductor layer 105 the insulating layer 103 may be formed in substrate 100. A depth of penetration hole 115 may be greater than the sum of thicknesses of first interlayer dielectric film 110, semiconductor layer 105 and insulating layer 103. Thus, a bottom surface of penetration hole 115 may be located beneath the second surface30 of insulating layer 103 and may be formed in semiconductor substrate 101.

Penetration hole 115 may be formed by forming a mask pattern on first interlayer dielectric film 110, and then successively etching first interlayer dielectric film 110, semiconductor layer 105 and insulating layer 103 using the mask pattern as an etching mask. The etching process may be a dry etching process. According to an exemplary embodiment, forming penetration hole 115 may include at least one dry etching process. For example, etching first interlayer dielectric film 110, etching semiconductor layer 105 and etching a portion of insulating layer 103 may be performed by different dry etching processes respectively. Alternatively, first interlayer dielectric film 110, semiconductor layer 105 and a portion of insulating layer 103 may be successively etched by one dry etching process.

A spacer film 120 may be conformally formed in penetration hole 115. Spacer film 120 may be formed by a CVD process or an atomic layer deposition (ALD) process. Spacer film 120 may include at least one of silicon oxide, silicon nitride or silicon oxynitride.

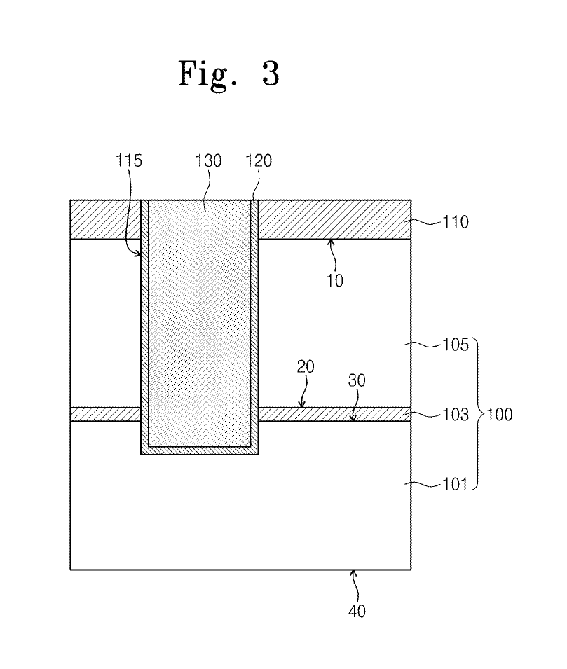

Referring to FIG. 3, a through electrode 130 may be formed by filling penetration hole 115. Since a depth of penetration hole 115 is greater than the sum of thicknesses of first interlayer dielectric film 110, semiconductor layer 105 and insulating layer 103, through electrode 130 may include a protrusive portion protruding from the second surface 30 of insulating layer 103. Trough electrode 130 may include conductive material. For example, insulating layer 103 may include at least one of tungsten, polycrystalline silicon, copper or aluminum.

Trough electrode 130 may be formed by forming a conductive film on first interlayer dielectric film 110 to fill penetration hole 115, and then removing the conductive film on first interlayer dielectric film 110 to expose first interlayer dielectric film 110. The conductive film may be deposited by a chemical vapor deposition (CVD) process or a physical vapor deposition (PVD) process. Removing the conductive film on the first interlayer dielectric film 110 may be performed by a chemical mechanical polishing (CMP) process.

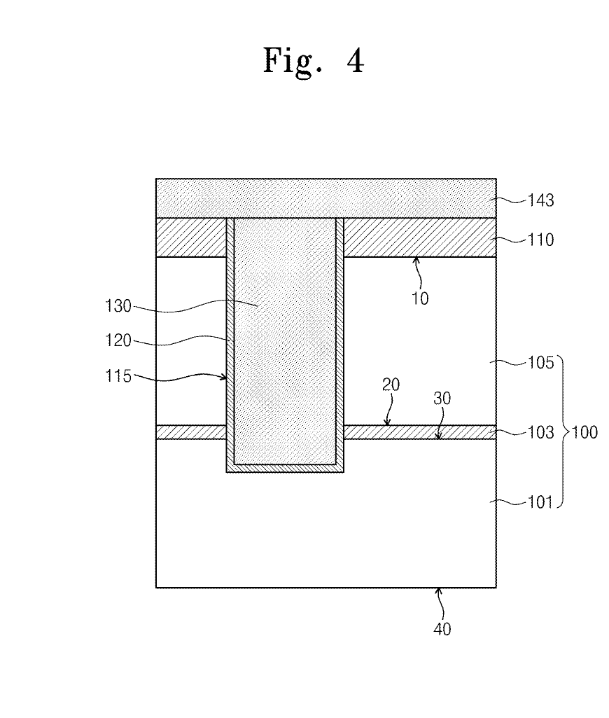

Referring to FIGS. 4 through 6, an interconnection structure 140 electrically connected to through electrode 130 may be formed on first interlayer dielectric film 110. Interconnection structure 140 may include a first interconnection 143, a via contact 145 and a second interconnection 147.

Referring to FIG. 4, first interconnection 143, electrically connected to through electrode 130, may be formed on first interlayer dielectric film 110. First interconnection 143 may include at least one of metal (e.g., aluminum, copper, titanium and tantalum) or conductive nitride (e.g., titanium nitride and tantalum nitride).

First interconnection 143 may be formed by forming a conductive film on first interlayer dielectric film 110, and then patterning the conductive film.

Alternatively, first interconnection 143 may be formed by a damascene process. According to damascene process, first interconnection 143 may be formed by forming a mold layer including an opening on first interlayer dielectric film 110, and then filling the opening with conductive material. The mold layer may include insulating material. For example, the mold layer may include at least one of silicon oxide, silicon nitride or silicon oxynitride. Also, a bottom surface of the opening may expose a portion of first interlayer dielectric film 110 and through electrode 130. Thus, first interconnection 143 may contact through electrode 130.

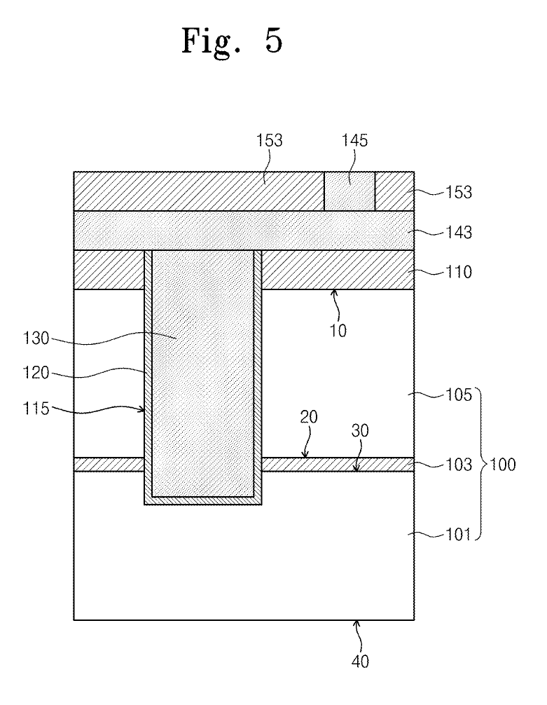

Referring to FIG. 5, a via contact 145 which is in contact with first interconnection 145 may be formed. Via contact 145 may include at least one of metal (e.g., tungsten, aluminum, copper, titanium and tantalum) or conductive nitride (e.g., titanium nitride and tantalum nitride).

A via contact hole exposing a top surface of the first interconnection 143 may be formed by depositing a second interlayer dielectric film 153 on first interconnection 143, and then etching second interlayer dielectric film 153. Via contact 145 may be formed by filling the via contact hole with conductive material. Since the via contact hole exposes a top surface of the interconnection 143, via contact 145 may contact first interconnection 143.

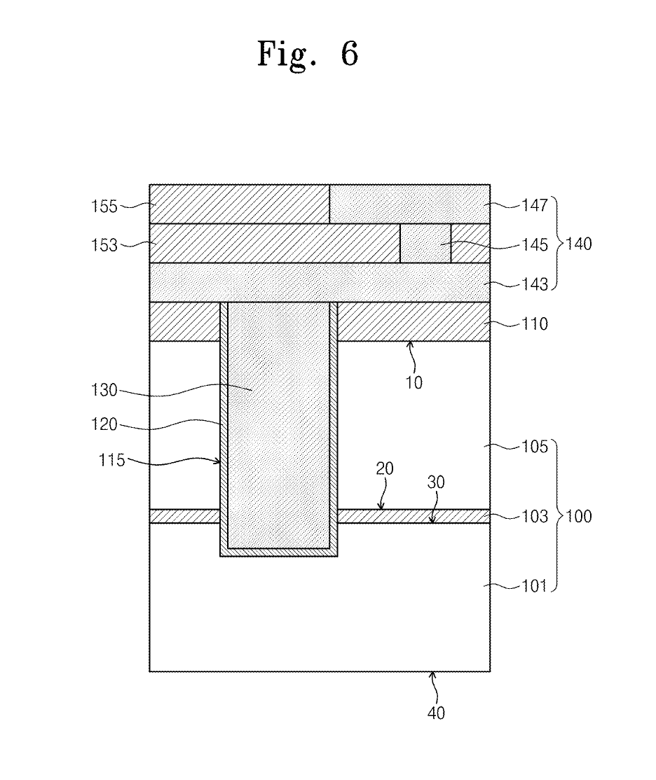

Referring to FIG. 6, a second interconnection 147 electrically connected to via contact 145 may be formed on second interlayer dielectric film 153. Second interconnection 145 may include at least one of metal (e.g., aluminum, copper, titanium and tantalum) or conductive nitride (e.g., titanium nitride and tantalum nitride). Second interconnection 147 may be formed by a patterning process or a damascene process.

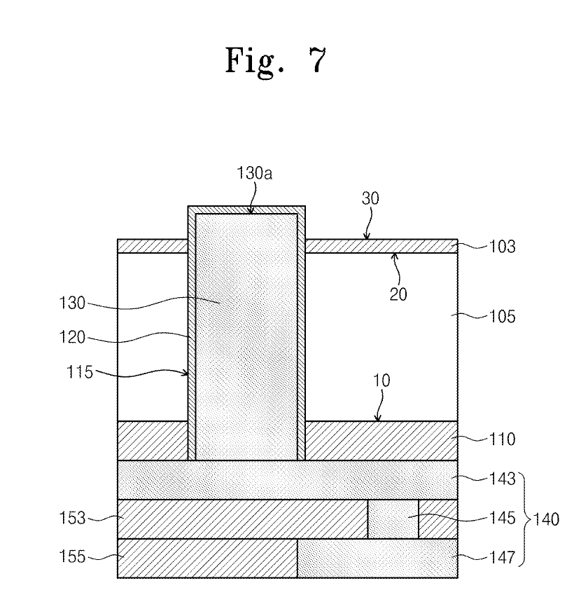

Referring to FIG. 7, semiconductor substrate 101 is removed to expose second surface 30 of insulating layer 103. Through electrode 130 may include a first end surface adjacent to active surface 10 of semiconductor layer 105 and a second end surface 130a adjacent to inactive surface 20 of semiconductor layer 105. Second end surface 130a of through electrode 130 may be one surface constituting the protrusive portion of through electrode. Thus, spacer film 120 covering second end surface 130a of through electrode 130 may be exposed by removing semiconductor substrate 101.

Removing semiconductor substrate 101 may be performed by a grinding process, a dry etching process, a wet etching process or a chemical mechanical polishing (CMP) process.

When removing semiconductor substrate 101, insulating layer 103 may be used as an etch-stop layer. In the case of not using a substrate including insulating layer 103, a through electrode may be formed on a substrate and a process of etching a back side of the substrate may be performed to expose the through electrode. At this time, since there is no etch-stop layer, the substrate etched by the process of etching a back side of the substrate may have a thickness deviation. The thickness deviation may affect subsequent processes performed on the etched substrate. As a result, problems may occur. According to exemplary embodiments, since insulating layer 103 is used as an etch-stop layer, the process of removing semiconductor substrate 101 may not affect a thickness of semiconductor layer 105. Thus, a deviation of thickness of semiconductor layer 105 may be minimized, thus minimizing an abnormal process which may occur in the subsequent process.

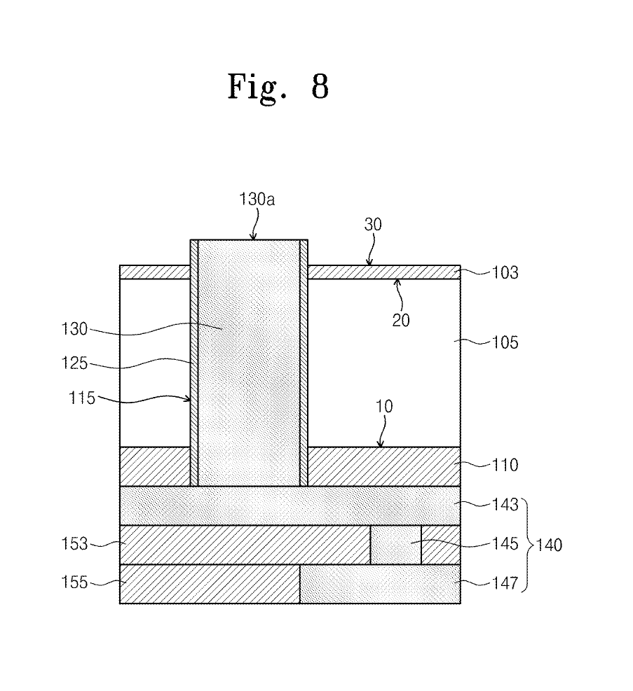

Referring to FIG. 8, spacer film 120 covering the second end surface 130a of through electrode 130 is removed to form a spacer 125 disposed between through electrode 130 and an inner sidewall of penetration hole 115. Second end surface 130a of through electrode 130 may be exposed by the process of forming spacer 125.

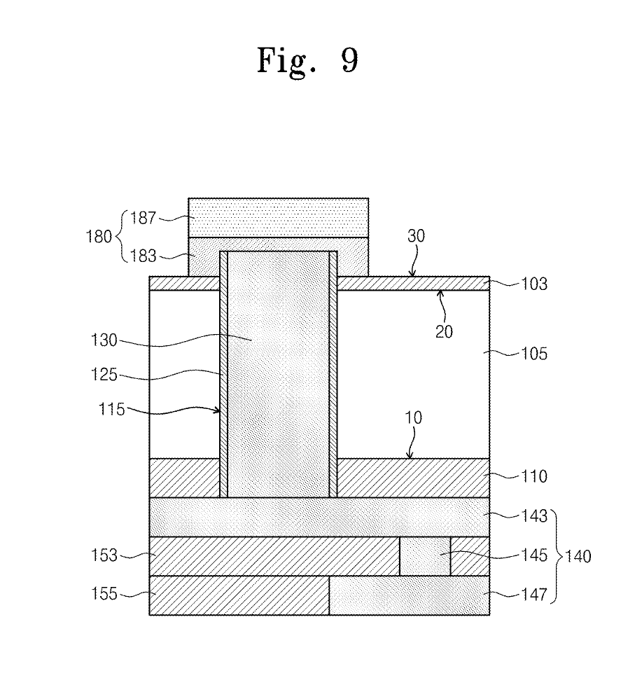

According to an exemplary embodiment, as illustrated in FIG. 9, a bump 180 which is in contact with the protrusive portion of exposed through electrode 130 may be further formed. Bump 180 may include a first conductive pad 183 and a second conductive pad 187. First and second conductive pads 183 and 187 may include metal. For example, first and second conductive pads 183 and 187 may include at least one of aluminum, copper or nickel. According to an exemplary embodiment, first and second conductive pads 183 and 187 may each include different metals. For example, first conductive pad 183 may include copper and second conductive pad 187 may include nickel. However, the exemplary embodiment may not be limited thereto. According to an exemplary embodiment, unlike the illustration in the drawing, a conductive pad which is in contact with the protrusive portion of exposed through electrode 130 is formed, and then a solder may be formed on the conductive pad. According to another exemplary embodiment, forming bump 180 may be omitted. Herein, the protrusive portion of exposed through electrode 130 may perform the same function as bump 180. That is, the protrusive portion of exposed through electrode 130 may be directly connected to at least one of a printed circuit board (PCB), an interposer device or another semiconductor chip.

As described above, the semiconductor chip in accordance with the exemplary embodiments may form insulating layer 103 on the inactive surface 20 of the semiconductor layer 105 without performing additional processes. Thus, problems that may occur as a result of additional processes needed to form insulating layer 103, can be minimized, and a semiconductor chip having improved reliability and characteristic may be realized.

Hereinafter, a semiconductor chip in accordance with an alternate exemplary embodiment of the inventive concept will be described. FIG. 9 is a cross sectional view for illustrating a semiconductor chip in accordance with an exemplary embodiment.

Referring to FIG. 9, the semiconductor chip may include a semiconductor layer 105 having an active surface 10 and an inactive surface 20 facing each other. Active surface 10 of semiconductor layer 105 may include at least one of a transistor, a diode, a capacitor or a resistor, etc., constituting a semiconductor device. Alternatively, inactive surface 20 of semiconductor layer 105 may not include the structures described above. Semiconductor layer 105 may include semiconductor material. For example, semiconductor layer 105 may include at least one of silicon or germanium. Semiconductor layer 105 may have a uniform thickness. Thus, an occurrence of problems resulting from a thickness deviation of semiconductor layer 105, may be minimized.

An insulating layer 103 including a first surface and a second surface 30 facing each other may be disposed on the inactive surface 20 of semiconductor layer 105. In this situation, inactive surface 20 of the semiconductor layer 105 may be in contact with first surface of insulating layer 103. Insulating layer 103 may include at least one of silicon oxide, silicon nitride or silicon oxynitride.

A first interlayer dielectric film 110 may be disposed on the active surface 10 of semiconductor layer 105. The first interlayer dielectric film 110 may be formed by a chemical vapor deposition (CMP) process or a physical vapor deposition (PVD) process. The first interlayer dielectric film 110 may include at least one of silicon oxide, silicon nitride or silicon oxynitride.

The semiconductor chip may include a through electrode 130 formed in a penetration hole 115 sequentially penetrating first interlayer dielectric film 110, semiconductor layer 105 and insulating layer 103.

Through electrode 130 may include conductive material. For example, through electrode 130 may include at least one of tungsten, polycrystalline silicon, copper or aluminum. Through electrode 130 may include a first end surface adjacent to active surface 10 of semiconductor layer 105 and a second end surface 130a adjacent to inactive surface 20 of the semiconductor layer 105.

Through electrode 130 may include a protrusive portion protruding from second surface 30 of insulating layer 103. Second end surface 130a may be one surface constituting the protrusive portion of through electrode 130. Since through electrode 130 includes the protrusive portion, a distance between active surface 10 of semiconductor layer 105 and inactive surface 20 of semiconductor layer 105 may be smaller than a distance between active surface 10 of semiconductor layer 105 and second end surface 130a of through electrode 130.

Spacer 125 may be interposed between through electrode 130 and an inner sidewall of penetration hole 115. Spacer 125 may include at least one of silicon oxide, silicon nitride or silicon oxynitride. According to an exemplary embodiment, spacer 125 may be omitted.

An interconnection structure 140 may be disposed on interlayer dielectric layer 110. Interconnection structure 140 may include a first interconnection 143, a second interconnection 147 and a via contact 145 disposed between first and second interconnections 143 and 147.

First interconnection 143 may be electrically connected to through electrode 130. First interconnection 143 may include at least one of metal (e.g., aluminum, copper, titanium and tantalum) or conductive nitride (e.g., titanium nitride and tantalum nitride). First interconnection 143 may be formed by a patterning process or a damascene process.

Via contact 145 may be disposed on first interconnection 143. Via contact 145 may be electrically connected to first and second interconnections 143 and 147. Via contact 145 may include at least one of metal (e.g., tungsten, aluminum, copper, titanium and tantalum) or conductive nitride (e.g., titanium nitride and tantalum nitride).

Second interconnection 147, electrically connected to the via contact 145, may be disposed on a second interlayer dielectric film 153. Second interconnection 147 may include at least one of metal (e.g., aluminum, copper, titanium and tantalum) or conductive nitride (e.g., titanium nitride and tantalum nitride). Second interconnection 147 may be formed by a patterning process or a damascene process.

A bump 180 electrically connected to the protrusive portion of through electrode 130 may be disposed on insulating layer 103. Bump 180 may include a first conductive pad 183 and a second conductive pad 187. First and second conductive pads 183 and 187 may include metal. For example, first and second conductive pads 183 and 187 may include at least one of aluminum, copper or nickel. According to an exemplary embodiment, first and second conductive pads 183 and 187 may include different metals from each other. For example, first conductive pad 183 may include copper and the second conductive pad 187 may include nickel. However, the exemplary embodiments may not be limited thereto. According to an exemplary embodiment, unlike the illustration in the drawing, the semiconductor chip may include a conductive pad which is in contact with the protrusive portion of exposed through electrode 130 and a solder formed on the conductive pad. According to another exemplary embodiment, bump 180 may be omitted. The protrusive portion of through electrode 130 may perform the same function as bump 180. That is, the protrusive portion of through electrode 130 may be directly connected to at least one of a printed circuit board (PCB), an interposer device or another semiconductor chip.

### Second Embodiment

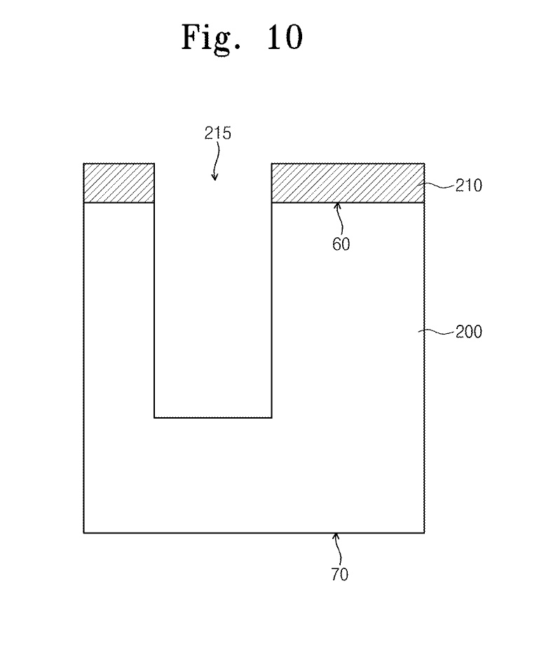

Hereinafter, a method of forming a semiconductor chip in accordance with another exemplary embodiment will be described. FIGS. 10 through 17 are cross sectional views illustrating a method of forming a semiconductor chip in accordance with another exemplary embodiment.

Referring to FIG. 10, a bulk substrate 200 including a front side 60 and a back side 70 facing each other is prepared. Front side 60 of bulk substrate 200 may include at least one of a transistor, a diode, a capacitor or a resistor, etc. Back side 70 of bulk substrate 200 may not include the aforementioned structure. Bulk substrate 200 may include semiconductor material. For example, bulk substrate 200 may include at least one of silicon or germanium.

A first interlayer dielectric film 210 may be formed on front side 60 of bulk substrate 200. First interlayer dielectric film 210 may include at least one of silicon oxide, silicon nitride or silicon oxynitride.

Referring back to FIG. 10, a hole 215 extending from a top surface of first interlayer dielectric film 210 toward back side 70 of bulk substrate 200 may be formed in bulk substrate 200. Hole 215 may be formed by forming a mask pattern on first interlayer dielectric film 210, and then etching first interlayer dielectric film 210 and bulk substrate 200 using the mask pattern as an etching mask. According to an exemplary embodiment, forming hole 215 may include at least one dry etching process. For example, etching first interlayer dielectric film 210 and bulk substrate 200 to form hole 215 may be performed by different dry etching processes, respectively. Alternatively, first interlayer dielectric film 210 and bulk substrate 200 may be etched to form hole 215 by a dry etching process.

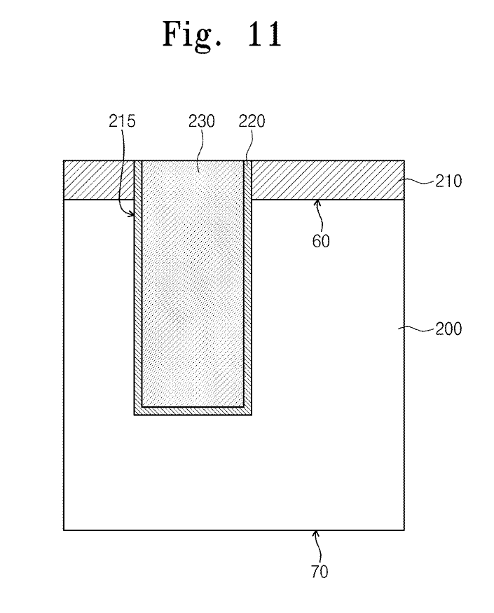

Referring to FIG. 11, a spacer film 220 may be conformally formed inside hole 215. Spacer film 220 may be formed by a chemical vapor deposition (CVD) process or an atomic layer deposition (ALD) process. Spacer film 220 may include at least one of silicon oxide, silicon nitride or silicon oxynitride.

Through electrode 230 may be formed in the hole including spacer film 220. Through electrode 230 may include conductive material. For example, through electrode 230 may include at least one of tungsten, polycrystalline silicon, copper or aluminum. Through electrode 230 may be formed by the same method as the method described with reference to FIG. 3, in the aforementioned exemplary embodiment.

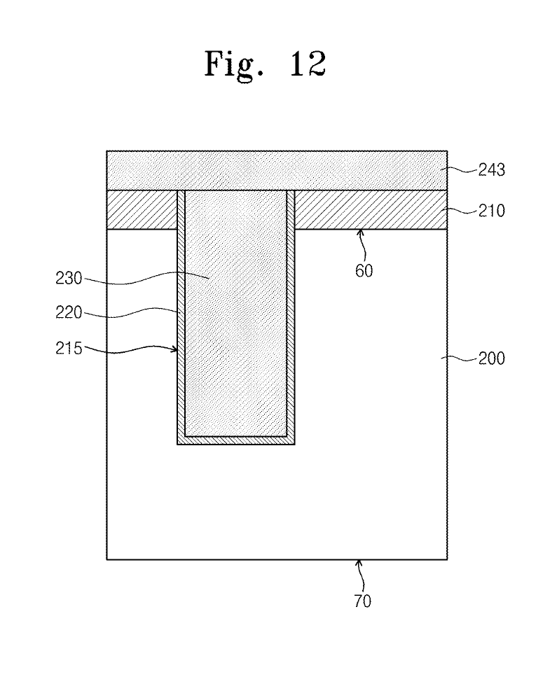

Referring to FIGS. 12 through 14, an interconnection structure 240 electrically connected to through electrode 230 may be formed on first interlayer dielectric film 210. Interconnection structure 240 may include a first interconnection 243, a via contact 245 and a second interconnection 247.

Referring to FIG. 12, first interconnection 243 electrically connected to through electrode 230 may be formed on first interlayer dielectric film 210. First interconnection 243 may be the same type as first interconnection 143 described with reference to FIG. 4 in the aforementioned exemplary embodiment and may be formed by the same method as the method of forming first interconnection 143. First interconnection 243 may include the same material as first interconnection 143, as described in the aforementioned exemplary embodiment.

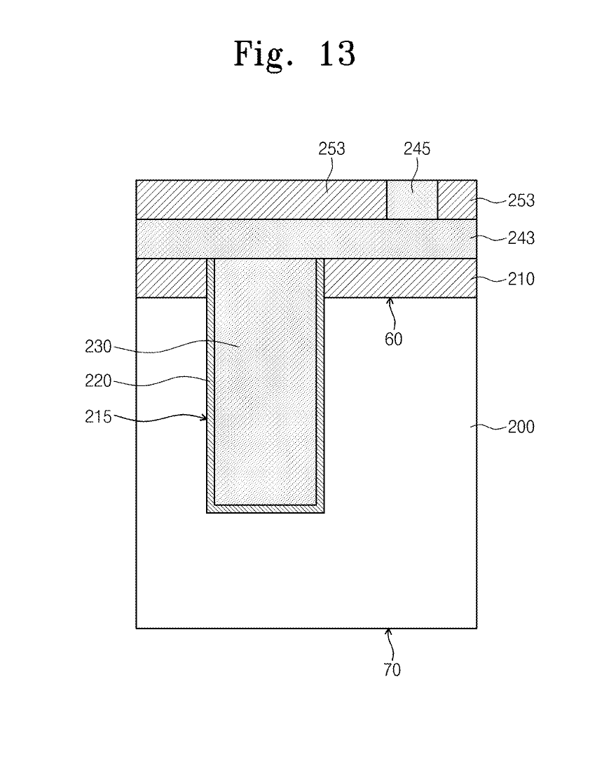

Referring to FIG. 13, via contact 245, electrically connected to first interconnection 243, may be formed. Via contact 245 may be the same type as via contact 145 described with reference to FIG. 5 in the aforementioned exemplary embodiment, and may be formed by the same method as the method of forming via contact 145. Also, via contact 245 may include the same material as the via contact 145 described in the aforementioned exemplary embodiment.

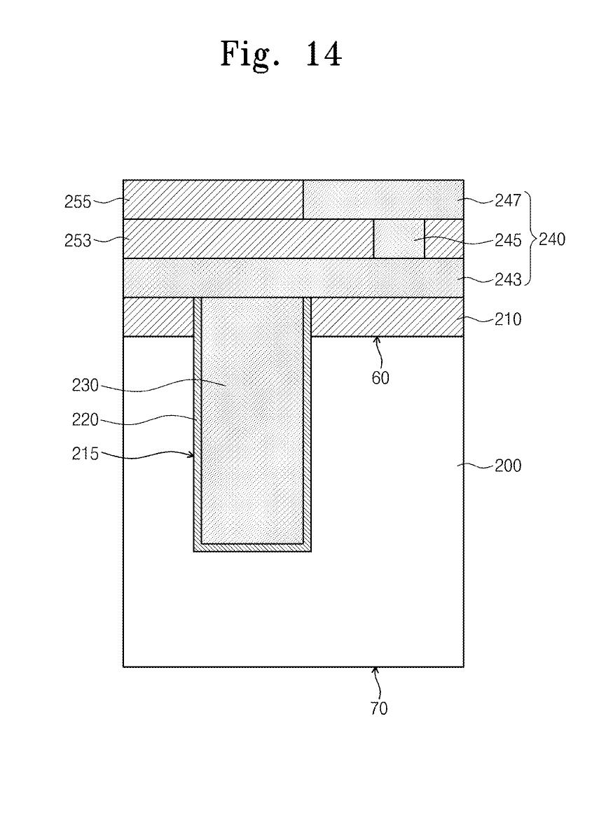

Referring to FIG. 14, second interconnection 247 electrically connected to via contact 245 may be formed on second interlayer dielectric film 253. Second interconnection 247 may be the same type as second interconnection 147 described with reference to FIG. 6 in the aforementioned exemplary embodiment and may be formed by the same method as the method of forming second interconnection 147. Second interconnection 247 may include the same material as second interconnection 147 described in the aforementioned exemplary embodiment.

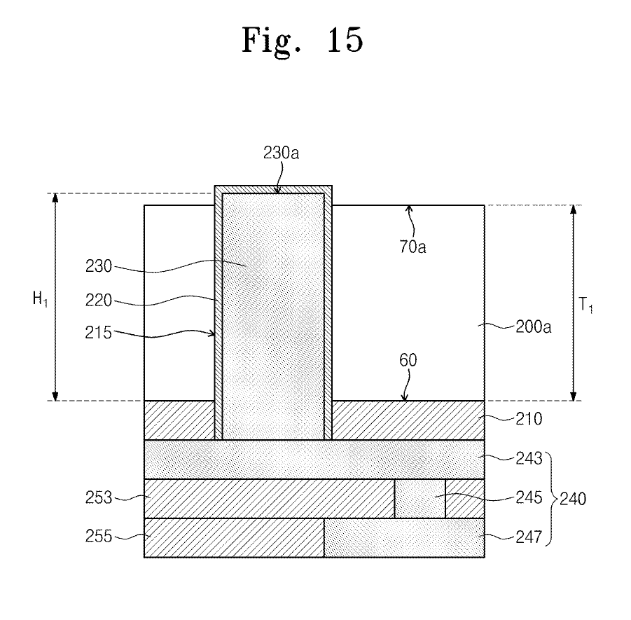

Referring to FIG. 15, a thickness of bulk substrate 200 may be reduced by etching back side 70 of bulk substrate 200. An etched bulk substrate 200a and an etched back side 70a may be defined by etching the back side 70 of bulk substrate 200. According to the present exemplary embodiment, through electrode 230 may include a first end surface adjacent to front side 60 of bulk substrate 200 and a second end surface 230a adjacent to etched back side 70a of the bulk substrate 200. Spacer film 220 covering the second end surface 230a of through electrode 230 may be exposed by etching bulk substrate 200. A thickness T1 of etched bulk substrate 200a may be equal to or smaller than a height H1 between front side 60 of etched bulk substrate 200a and second end surface 230a of through electrode 230. In the situation that thickness T1 of etched bulk substrate 200a may be smaller than height H1 between front side 60 of etched bulk substrate 200a and second end surface 230a of through electrode 230, through electrode 230 may include a protrusive portion protruding from etched back side 70a of etched bulk substrate 200a. Etching back side 70 of bulk substrate 200 may be performed by at least one of a grinding process, a dry etching process, a wet etching process or a chemical mechanical polishing (CMP) process.

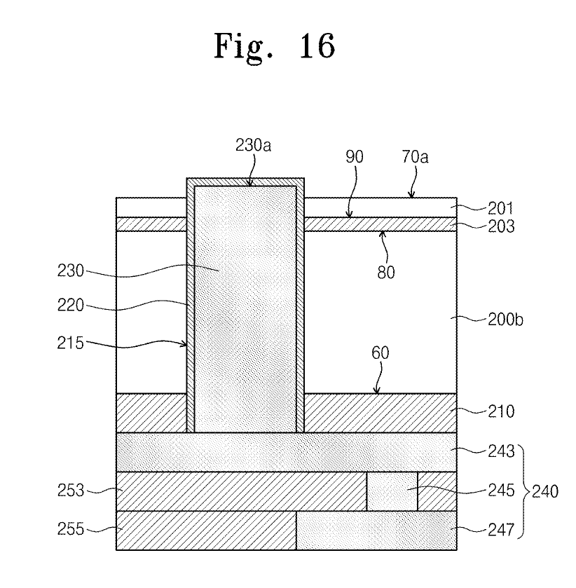

Referring to FIG. 16, an insulating layer 203 may be formed in etched bulk substrate 200a by providing elements for insulating properties into etched back side 70a. Insulating layer 203 may include a first surface 80 and a second surface 90 facing each other. The elements for insulating properties may react to semiconductor material included in etched bulk substrate 200a to form insulating material. For example, the elements for insulating properties may include at least one of oxygen or nitrogen. Insulating layer 203 may include at least one of silicon oxide, silicon nitride or silicon oxynitride.

As illustrated in the drawing, the elements for insulating properties are provided into etched bulk substrate 200a and thereby insulating layer 203 may be formed at a predetermined depth from etched back side 70a. In this situation, a portion of etched bulk substrate 200a between etched back side 70a and second surface 90 of the insulating layer 203 may be defined as a capping layer 201. A portion of etched bulk substrate 200a between front side 60 of etched bulk substrate 200a and the first surface of insulating layer 203 may be defined as a semiconductor layer 200b. Thus, insulating layer 203 may be interposed between capping layer 201 and semiconductor layer 200b. Semiconductor layer 200b may include an inactive surface 80 adjacent to the first surface of insulating layer 203 and front side 60 facing the inactive surface 80. Capping layer 201 may include a back side adjacent to second surface 90 of insulating layer 203 and etched back side 70a, facing the etched back side 7a. A thickness of capping layer 201 may be substantially uniform. Semiconductor layer 200b and capping layer 201 may constitute a portion of etched bulk substrate 200a. Thus, semiconductor layer 200b and capping layer 201 may include the same semiconductor material as etched bulk substrate 200a.

Unlike the illustration in the drawing, insulating layer 203 may be formed on a surface of etched back side 70a of etched bulk substrate 200a. In this situation, a portion of etched bulk substrate 200a between front side 60 of etched bulk substrate 200a and first surface of insulating layer 203 may be defined as a semiconductor layer. Thus, the first surface of insulating layer 203 is in contact with the semiconductor layer and second surface 90 of insulating layer 203 may be exposed.

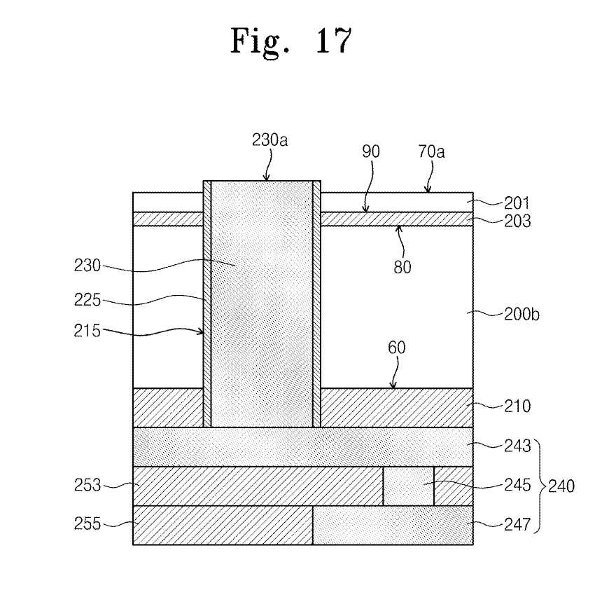

Referring to FIG. 17, spacer film 220 covering second end surface 230a of through electrode 230 may be removed to form a spacer 225 disposed between through electrode 230 and an inner sidewall of hole 215. Second end surface 230a of through electrode 230 may be exposed.

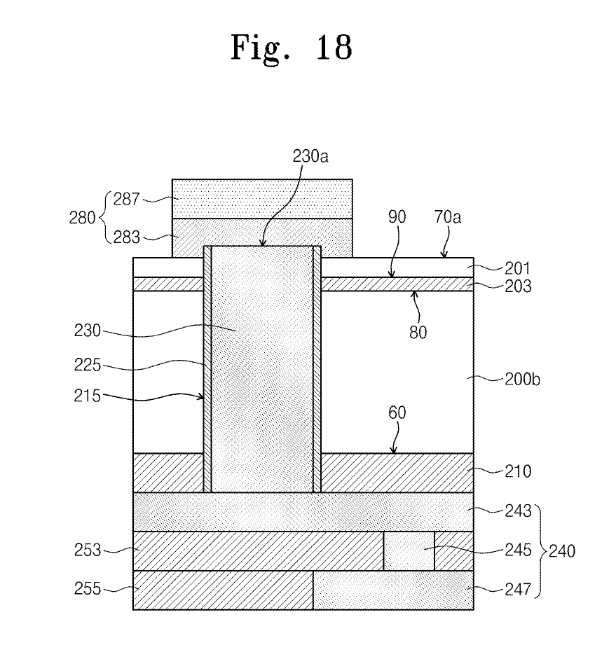

According to an exemplary embodiment, as illustrated in FIG. 18, a bump 280 which is in contact with second end surface 230a of exposed through electrode 230 may be further formed. Bump 280 may be the same type as bump 180 described with reference to FIG. 9 in the aforementioned exemplary embodiment and may be formed by the same method as the method of forming bump 180. Also, bump 280 may include the same material as bump 180 described in the aforementioned exemplary embodiment. However, the exemplary embodiment may not be limited thereto. Unlike the illustration in the drawing, a conductive pad which is in contact with one surface of exposed through electrode 230 is formed, and then a solder may be formed on the conductive pad. According to another exemplary embodiment, forming bump 280 may be omitted. In the situation where through electrode 230 includes a protrusive portion protruding from etched back side 70a, the protrusive portion may perform the same function as bump 280. That is, the protrusive portion may be directly connected to at least one of a printed circuit board (PCB), an interposer device or another semiconductor chip.

According to the present exemplary embodiment, insulating layer 203 may be formed in etched bulk substrate 200a by providing elements for insulating properties. If forming an insulating layer on etched back side 70a and exposing the through electrode by etching a portion of the insulating layer, the number of processes required for forming the insulating layer may increase, thereby causing the manufacturing cost of a semiconductor chip to increase. Also, problems may occur in processes for forming an insulating layer. However, according to the exemplary embodiment, since insulating layer 203 may be formed by an element implanting process, the manufacturing cost of a semiconductor chip may be reduced and a semiconductor chip having improved reliability and characteristic may be realized, by minimizing the occurrence of problems.

Hereinafter, a semiconductor chip in accordance with another exemplary embodiment of the inventive concept will be described. FIG. 18 is a cross sectional view for illustrating a semiconductor chip in accordance with another exemplary embodiment.

Referring to FIG. 18, a semiconductor chip in accordance with the present exemplary embodiment may include a semiconductor layer 200b having an active surface 60 and an inactive surface 80 facing each other. Active surface 60 semiconductor layer 200b may include at least one of a transistor, a diode, a capacitor or a resistor, etc., constituting the semiconductor device. On the other hand, inactive surface 80 of semiconductor layer 200b may not include the aforementioned structure. Semiconductor layer 200b may include semiconductor material. For example, the semiconductor layer 200b may include at least one of silicon or germanium.

An insulating layer 203 including a first surface and a second surface 90 facing away from each other may be disposed on inactive surface 80 of semiconductor layer 200b. In this situation, inactive surface 80 of semiconductor layer 200b and first surface of the insulating layer 203 may be in contact with each other. Insulating layer 203 may include at least one of silicon oxide, silicon nitride and silicon oxynitride. Insulating layer 203 may be formed by providing elements for insulating properties to one surface of the bulk substrate, as described above.

A first interlayer dielectric film 210 may be formed on active surface 60 of semiconductor layer 200b. First interlayer dielectric film 210 may be formed by a chemical vapor deposition (CVD) process or a physical vapor deposition (PVD) process. First interlayer dielectric film 210 may include at least one of silicon oxide, silicon nitride or silicon oxynitride.

A capping layer 201 may be disposed on second surface 90 of the insulating layer 203. Capping layer 201 may include a first surface adjacent to the second surface 90 of the insulating layer 203 and a second surface 70a facing the first surface. Capping layer 201 may include semiconductor material. Capping layer 201 may include at least one of silicon or germanium. According to an exemplary embodiment, capping layer 201 may include the same material as semiconductor layer 200b.

The semiconductor chip may include a through electrode 230 formed in a penetration hole 215 sequentially penetrating first interlayer dielectric film 210, semiconductor layer 200b, insulating layer 203 and capping layer 201. Through electrode 230 may include a first end surface adjacent to the active surface 60 of the semiconductor layer 200b and a second end surface 230a adjacent to second surface 70a of capping layer 201.

Through electrode 230 may include conductive material. For example, through electrode 230 may include at least one of tungsten, polycrystalline silicon, copper or aluminum. Through electrode 230 may include a protrusive portion protruding from second surface 90 of insulating layer 203. Thus, a distance between active surface 60 of semiconductor layer 200b and inactive surface 80 of semiconductor layer 200b may be smaller than a distance between active surface 60 of the semiconductor layer 200b and second end surface 230a of through electrode 230.

Second surface 90 of capping layer 201 may be located at a level equal to or lower than second end surface 230a of through electrode 230. In the situation where the second surface 90 of capping layer 201 and second end surface 230a of through electrode 230 are located at a same level, one surface of the protrusive portion of through electrode 230 may be surrounded by capping layer 201.

A spacer 225 may be interposed between through electrode 230 and an inner sidewall of hole 215. Spacer 225 may include at least one of silicon oxide, silicon nitride or silicon oxynitride. According to an exemplary embodiment, spacer 225 may be omitted.

An interconnection structure 240 may be formed on first interlayer dielectric film 210. Interconnection structure 240 may include a first interconnection 243, a second interconnection 247 and a via contact 245 disposed between first interconnection 243 and second interconnection 247.

First interconnection 243 may be electrically connected to through electrode 230. First interconnection 243 may include at least one of metal (e.g., aluminum, copper, titanium and tantalum) or conductive nitride (e.g., titanium nitride and tantalum nitride). First interconnection 243 may be formed by a patterning process or a damascene process.

Via contact 245 may be disposed on first interconnection 243. Via contact 245 may be electrically connected to first and second interconnections 243 and 247. Via contact 245 may include at least one of metal (e.g., tungsten, aluminum, copper, titanium and tantalum) or conductive nitride (e.g., titanium nitride and tantalum nitride).

A second interconnection 247, electrically connected to via contact 245, may be disposed on a second interlayer dielectric film 253. Second interconnection 247 may include at least one of metal (e.g., aluminum, copper, titanium and tantalum) or conductive nitride (e.g., titanium nitride and tantalum nitride). Second interconnection 247 may be formed by a patterning process or a damascene process.

A bump 280 may be electrically connected to second end surface 230a of through electrode 230. Bump 280 may be the same type as bump 180 described with reference to FIG. 9 in the aforementioned exemplary embodiment and may be formed by the same method as the method of forming bump 180. Also, the bump 280 may include the same material as bump 180 described in the aforementioned exemplary embodiment. However, the exemplary embodiment may not be limited thereto. According to this exemplary embodiment, unlike the illustration in the drawing, a conductive pad is formed, and is in contact with the protrusive portion of exposed through electrode 230, and then a solder may be formed on the conductive pad. According to another exemplary embodiment, forming bump 280 may be omitted. In the situation where through electrode 230 includes a protrusive portion protruding from etched back side 70a, the protrusive portion may perform the same function as bump 280. That is, the protrusive portion may be directly connected to at least one of a printed circuit board (PCB), an interposer device or another semiconductor chip.

As described above, a semiconductor chip in accordance with an exemplary embodiment may constitute a backside insulating structure of the semiconductor chip, using a substrate including an insulating film. Since a back side etching process is performed using the insulating film included in the substrate as an etch-stop layer, a thickness of the semiconductor chip may be uniformly maintained. Thus, a semiconductor chip may be formed having improved reliability and improved electrical characteristics.

The foregoing is illustrative of the inventive concept and is not to be construed as limiting thereof. Although a few exemplary embodiments of the inventive concept have been described, those skilled in the art will readily appreciate that many modifications are possible in the embodiments without materially departing from the novel teachings and advantages of the present invention. Accordingly, all such modifications are intended to be included within the scope of the exemplary embodiments as defined in the claims. The present invention is defined by the following claims, with equivalents of the claims to be included therein.

1. A semiconductor chip comprising:
a semiconductor layer including an active surface and an inactive surface facing each other;
an insulating layer including a first surface adjacent to the inactive surface and a second surface facing the first surface, the insulating layer being disposed on the inactive surface of the semiconductor layer; and
a hole penetrating the semiconductor layer and the insulating layer;
a through electrode filling the hole penetrating the semiconductor layer and the insulating layer, wherein the through electrode includes a protrusive portion protruding from the second surface of the insulating layer.

2. The semiconductor chip of claim 1, further comprising a spacer interposed between the through electrode and an inner sidewall of the hole.

3. The semiconductor chip of claim 1, further comprising an interconnection layer disposed on the active surface of the semiconductor layer and electrically connected to the through electrode.

4. The semiconductor chip of claim 1, further comprising a bump electrically connected to the protrusive portion of the through electrode.

5. The semiconductor chip of claim 1, further comprising a capping layer disposed on the second surface of the insulating layer.

6. The semiconductor chip of claim 5, wherein a thickness of the capping layer is equal to or less than a height of the protrusive portion of the through electrode.

7. The semiconductor chip of claim 5, wherein the capping layer comprises the same material as the semiconductor layer.

8. A method of forming a semiconductor chip comprising:
preparing a substrate comprising a semiconductor layer, a semiconductor substrate and an insulating layer disposed between the semiconductor layer and the semiconductor substrate, the insulating layer including a first surface adjacent to the semiconductor layer and a second surface adjacent to the semiconductor substrate;
forming a hole sequentially penetrating the semiconductor layer and the insulating layer, a bottom surface of the penetration hole being formed to be lower than the second surface of the insulating layer;
forming a through electrode in the hole; and
removing the semiconductor substrate using the insulating layer as an etch-stop layer.

9-12. (canceled)

13. A semiconductor chip comprising:
a semiconductor layer including an active surface and an inactive surface facing each other;
an insulating layer including a first surface adjacent to the inactive surface and a second surface facing the first surface, the insulating layer being adjacent to the inactive surface of the semiconductor layer; and
a through electrode electrode penetrating both the semiconductor layer and the insulating layer and protruding from the second surface of the insulating layer.
